(19) United States
(12) Patent Application Publication
(10) Pub. No.: US 2017/0077292 A1
(43) Pub. Date: Mar. 16, 2017

(54) TRENCH-GATE SEMICONDUCTOR DEVICE AND MANUFACTURING METHOD THEREOF

(71) Applicant: KABUSHIKI KAISHA TOYOTA JIDOSHOKKI, Kariya-shi (JP)

(72) Inventors: Yuichiro HOMMI, Kariya-shi (JP); Kenji ONO, Kariya-shi (JP); Kimiya AKAHORI, Kariya-shi (JP); Masayuki OKANO, Kariya-shi (JP)

(73) Assignee: KABUSHIKI KAISHA TOYOTA JIDOSHOKKI, Kariya-shi (JP)

(21) Appl. No.: 15/255,397

(22) Filed: Sep. 2, 2016

(30) Foreign Application Priority Data
Sep. 10, 2015 (JP) 2015-178646
May 9, 2016 (JP) 2016-093927

(51) Int. Cl. H01L 29/78; H01L 29/66; H01L 29/10; H01L 29/423

(52) U.S. Cl. CPC H01L 29/7813; H01L 29/4236; H01L 29/66734; H01L 29/1095

(57) ABSTRACT

A trench gate semiconductor device includes a high concentration first conductivity type semiconductor layer, a low concentration first conductivity type semiconductor layer, a second conductivity type semiconductor layer, and a trench. The second conductivity type semiconductor is provided at a position corresponding to the bottom-side portion of the trench. The junction between the first conductivity type semiconductor and the second conductivity type semiconductor is provided at the side of the bottom-side portion of the trench. The junction extends upward from the interface between the high concentration first conductivity type semiconductor layer and the low concentration first conductivity type semiconductor layer.

### BACKGROUND OF THE INVENTION

The present invention relates to a trench-gate semiconductor device and a method for manufacturing the device.

Japanese Laid-Open Patent Publication No. 2007-158275 discloses a semiconductor device that has a gate electrode and a p-type region. The gate electrode is arranged on the inner wall of a trench in a semiconductor substrate with a gate oxide film in between. The p-type region is located below the gate electrode. The p-type region is formed in the following manner. First, a trench portion is formed. Next, ion implantations of different accelerating voltages are performed. Then, thermal diffusion is performed to form the p-type region. The accelerating voltage is varied so that a p-type impurity is implanted and diffused at different depths, so that a vertically elongated p-type region is formed in the bottom of the trench. This improves the withstand voltage without degrading the on-resistance.

To further improve the withstand voltage, the p-type region must be further elongated vertically. If the accelerating voltage is further increased at the ion implantation, implantation of the impurity to depths d1, d2, d3 from the bottom of the trench 105 as shown in FIG. 17 will increase the width of the p-type region 108 as the depth increases. As a result, p-type regions 108 narrow an n-type region 102 that is located between two adjacent gate electrodes 107 (trenches 105) and allows a current to actually flow therethrough (the width W10 is diminished). This increases the on-resistance. In FIG. 17, the numeral 100 denotes a silicon substrate, the numeral 101 denotes an n⁺ region, the numeral 103 denotes a p-region, the numeral 104 denotes an n⁺ region, and the numeral 106 denotes a gate oxide film.

### SUMMARY OF THE INVENTION

Accordingly, it is an objective of the present invention to provide a trench-gate semiconductor device and a method for manufacturing the device that improve the withstand voltage without degrading the on-resistance.

In accordance with a first aspect of the present invention, a trench-gate semiconductor device is provided that includes a semiconductor substrate, a high concentration first conductivity type semiconductor layer, a low concentration first conductivity type semiconductor layer, a second conductivity type semiconductor layer, a first conductivity type semiconductor region, a trench, a gate insulation film, a gate electrode, a second conductivity type semiconductor, and a junction. The high concentration first conductivity type semiconductor layer is provided in the semiconductor substrate and contains a first conductivity type semiconductor. The low concentration first conductivity type semiconductor layer is provided on the high concentration first conductivity type semiconductor layer in a thickness direction of the semiconductor substrate to contact the high concentration first conductivity type semiconductor layer and contains the first conductivity type semiconductor. The second conductivity type semiconductor layer is provided on the low concentration first conductivity type semiconductor layer to contact the low concentration first conductivity type semiconductor layer. The first conductivity type semiconductor region is provided in a surface portion of the second conductivity type semiconductor layer. The trench extends through the first conductivity type semiconductor region and the second conductivity type semiconductor layer below the first conductivity type semiconductor region. The trench has a depth that is greater than or equal to a depth at which exists an interface between the high concentration first conductivity type semiconductor layer and the low concentration first conductivity type semiconductor layer. The gate insulation film is provided in the trench. The gate electrode is provided in the trench via the gate insulation film. The second conductivity type semiconductor is provided at a position corresponding to a bottom-side portion of the trench. The junction is located between the first conductivity type semiconductor and the second conductivity type semiconductor. The junction is provided at a side of the bottom-side portion of the trench. The junction extends upward from the interface between the high concentration first conductivity type semiconductor layer and the low concentration first conductivity type semiconductor layer.

In accordance with a second aspect of the present invention, a method for manufacturing a trench-gate semiconductor device is provided. The method includes: forming a high concentration first conductivity type semiconductor layer on a semiconductor substrate; forming a low concentration first conductivity type semiconductor layer on the high concentration first conductivity type semiconductor layer in a thickness direction of the semiconductor substrate, such that the low concentration first conductivity type semiconductor layer contacts the high concentration first conductivity type semiconductor layer; forming a second conductivity type semiconductor layer on the low concentration first conductivity type semiconductor layer to contact the low concentration first conductivity type semiconductor layer; forming a first conductivity type semiconductor region in a surface portion of the second conductivity type semiconductor layer; forming a trench, which extends through the first conductivity type semiconductor region and the second conductivity type semiconductor layer below the first conductivity type semiconductor region, wherein the trench has a depth that is greater than or equal to a depth at which exists an interface between the high concentration first conductivity type semiconductor layer and the low concentration first conductivity type semiconductor layer; after the forming of the trench, embedding a second conductivity type impurity doped oxide film in the trench; in the embedding, forming a junction between the first conductivity type semiconductor and the second conductivity type semiconductor such that the junction extends upward from an interface between the high concentration first conductivity type semiconductor layer and the low concentration first conductivity type semiconductor layer by diffusing the second conductivity type impurity from the second conductivity type impurity doped oxide film to the low concentration first conductivity type semiconductor layer through heat treatment; and forming a gate insulation film and a gate electrode in the trench.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a vertical cross-sectional view schematically showing a trench-gate MOSFET according to a first embodiment;

FIG. 2 is an explanatory vertical cross-sectional view schematically showing a step for manufacturing the trench-gate MOSFET;

FIG. 3 is an explanatory vertical cross-sectional view schematically showing a step for manufacturing the trench-gate MOSFET;

FIG. 4 is an explanatory vertical cross-sectional view schematically showing a step for manufacturing the trench-gate MOSFET;

FIG. 5 is an explanatory vertical cross-sectional view schematically showing a step for manufacturing the trench-gate MOSFET;

FIG. 6 is a vertical cross-sectional view schematically showing a trench-gate MOSFET according to a modification;

FIG. 7 is an explanatory vertical cross-sectional view schematically showing a step for manufacturing the trench-gate MOSFET;

FIG. 8 is a vertical cross-sectional view schematically showing a trench-gate MOSFET according to a second embodiment;

FIG. 9 is an explanatory vertical cross-sectional view schematically showing a step for manufacturing the trench-gate MOSFET;

FIG. 10A is a diagram showing the cross-sectional structure of FIG. 1;

FIG. 10B is a distribution chart of the amount of impurity averaged in the depth direction of the substrate;

FIG. 10C is a distribution chart of electricity field strength in the substrate depth direction when voltage is withstood;

FIG. 11A is a diagram showing the cross-sectional structure of FIG. 8;

FIG. 11B is a distribution chart of the amount of impurity averaged in the depth direction of the substrate;

FIG. 11C is a distribution chart of electricity field strength in the substrate depth direction when voltage is withstood;

FIG. 12 is a diagram showing the withstand voltage when the n concentration is uneven;

FIG. 13 is a vertical cross-sectional view schematically showing a trench-gate MOSFET according to a modification;

FIG. 14 is a vertical cross-sectional view schematically showing a trench-gate MOSFET according to another modification;

FIG. 15 is a vertical cross-sectional view schematically showing a trench-gate MOSFET according to a further modification;

FIG. 16 is a vertical cross-sectional view schematically showing a trench-gate MOSFET according to a yet another modification;

FIG. 17 is an explanatory vertical cross-sectional view schematically showing problems in a conventional semiconductor device.

### DETAILED DESCRIPTION OF THE PREFERRED EMBODIMENTS

### First Embodiment

A trench-gate MOSFET according to one embodiment of the present invention will now be described with reference to the drawings.

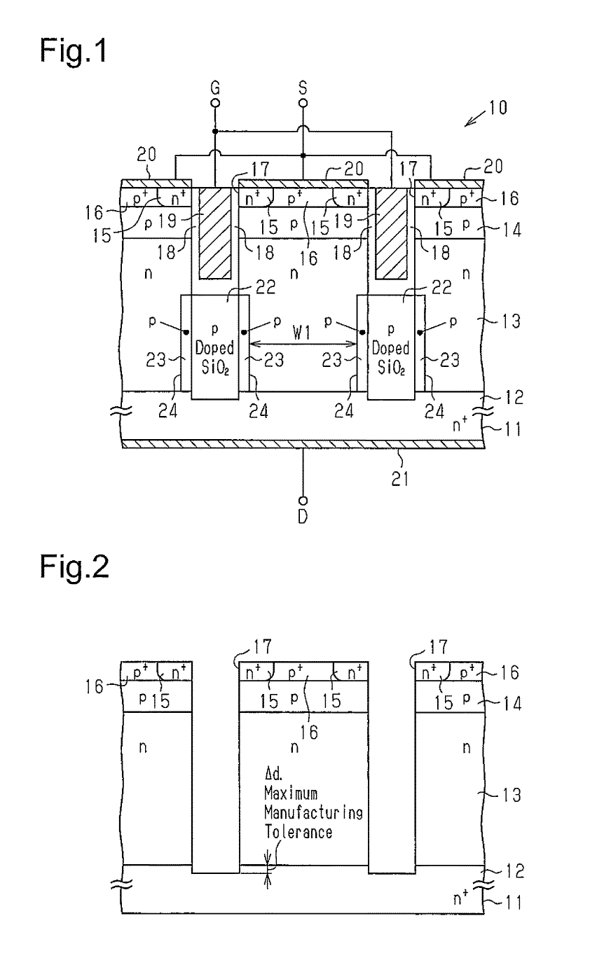

FIG. 1 is a vertical cross-sectional view schematically showing a trench-gate semiconductor device, which is a trench-gate MOSFET (chip) 10. The trench-gate MOSFET 10 is a vertical MOSFET, in which a plurality of trenches 17 is provided in a silicon substrate 11.

As shown in FIG. 1, the silicon substrate 11 includes an n⁺ silicon layer 12, an n silicon layer 13, and a p silicon layer (channel formation region) 14 arranged in the order from the bottom. A plurality of n⁺ source regions 15 is formed in the surface portion of the p silicon layer 14. The silicon substrate 11 has trenches 17 arranged side by side. Side walls of the trenches 17 are perpendicular to the upper surface of the silicon substrate 11.

Each trench 17 extends through the n⁺ source region 15 and the p silicon layer 14 to reach the n silicon layer 13. A polysilicon gate electrode 19 is arranged on (embedded in) the inner surface of each trench 17 via a gate oxide film 18. A drain electrode 21 is provided on the lower surface (the back side) of the silicon substrate 11. The upper surface of each polysilicon gate electrode 19 is coated with an insulation film (not shown). An aluminum source electrode 20 is arranged on the upper surface of the silicon substrate 11. The aluminum source electrode 20 is electrically connected to the n⁺ source regions 15 and a contact p⁺ regions 16 provided in the surface portion of the p silicon layer 14.

As described above, with respect to the thickness direction of the silicon substrate 11, which is a semiconductor substrate, the n silicon layer 13, which is a low concentration first conductivity type semiconductor layer, is provided on the n⁺ silicon layer 12, which is a high concentration first conductivity type semiconductor layer to contact the n⁺ silicon layer 12. The high concentration first conductivity type semiconductor layer and the low concentration first conductivity type semiconductor layer contain n-type silicon, which is a first conductivity type semiconductor. The p silicon layer 14, which is a second conductivity type semiconductor layer, is provided on the n silicon layer 13 to contact the n silicon layer 13. Further, the n⁺ source regions 15, which are first conductivity type semiconductor regions, are formed in the surface portion of the p silicon layer 14. The p silicon layer 14 is located below the n⁺ source regions 15. The trenches 17 extend through the n⁺ source regions 15 and the p silicon layer 14. A polysilicon gate electrode 19 is arranged in each trench 17 via a gate oxide film 18, which is a gate insulation film.

The trenches 17 have a depth that is greater than or equal to the depth at which the interface between the n⁺ silicon layer 12 and the n silicon layer 13 exists. That is, the trenches 17 extend to the interface between the n⁺ silicon layer 12 and the n silicon layer 13 or to a position deeper than the interface between the n⁺ silicon layer 12 and the n silicon layer 13.

A p-type impurity doped silicon oxide film 22, which is a second conductivity type impurity doped oxide film, is embedded in a bottom-side portion of each trench 17. A p silicon region 23, which is a second conductivity type semiconductor region, is provided on the side of each p-type impurity doped silicon oxide film 22. The p-type impurity doped silicon oxide films 22 and the p silicon regions 23 contain p-type silicon, which is a second conductivity type semiconductor. Each p silicon region 23 is formed by diffusing impurity from the corresponding p-type impurity doped silicon oxide film 22. The p silicon regions 23 are vertically longer than the p-type regions 108 in FIG. 17. The p silicon regions 23 extend upward from the interface between the n⁺ silicon layer 12 and the n silicon layer 13. The junction between each p silicon region 23 and the n silicon layer 13 is a p-n junction 24, which is located at the side of the bottom-side portion of each trench 17 and extends upward from the interface between the n⁺ silicon layer 12 and the n silicon layer 13. The gate oxide films 18 are provided on the p-type impurity doped silicon oxide films 22.

As described above, a p-n junction 24, which is a junction between the first conductivity type semiconductor and a second conductivity type semiconductor, is located at the side of the bottom-side portion of each trench 17 and extends upward from the interface between the n⁺ silicon layer 12 and the n silicon layer 13. More specifically, the p-n junction 24 is formed by the n silicon layer 13 and the p silicon region 23, which has been diffused from the p-type impurity doped silicon oxide film 22 embedded in the bottom-side portion of the trench 17.

A manufacturing method will now be described.

As shown in FIG. 2, a silicon substrate 11 is prepared in which an n silicon layer 13 is formed on an n⁺ silicon layer 12. A p silicon layer 14 is formed on the n silicon layer 13. A plurality of n⁺ source regions 15 and a contact p⁺ region 16 are formed in the surface portion of the p silicon layer 14. Then, trenches 17 are formed, the side walls of which are perpendicular to the upper surface of the silicon substrate 11. The trenches 17 have a depth that is greater than or equal to the depth at which the interface between the n⁺ silicon layer 12 and the n silicon layer 13 exists. That is, the trenches 17 are formed to extend to the interface between the n⁺ silicon layer 12 and the n silicon layer 13 or to a position deeper than the interface between the n⁺ silicon layer 12 and the n silicon layer 13. More specifically, the trenches 17 are formed to have a depth that is greater than the depth at which the interface between the n⁺ silicon layer 12 and the n silicon layer 13 exists by an amount greater than the maximum manufacturing tolerance (manufacturing variations) Δd.

The trenches 17 are formed to meet the above described conditions. Thus, even if the trench depths vary during manufacture, each trench 17 has a depth that reaches the interface between the n⁺ silicon layer 12 and the n silicon layer 13. Specifically, for example, chip formation regions in a wafer can vary in the trench depths between a center portion of the wafer and a peripheral portion. Even in such a case, each trench 17 has a depth that reaches at least the interface between n⁺ silicon layer 12 and the n silicon layer 13.

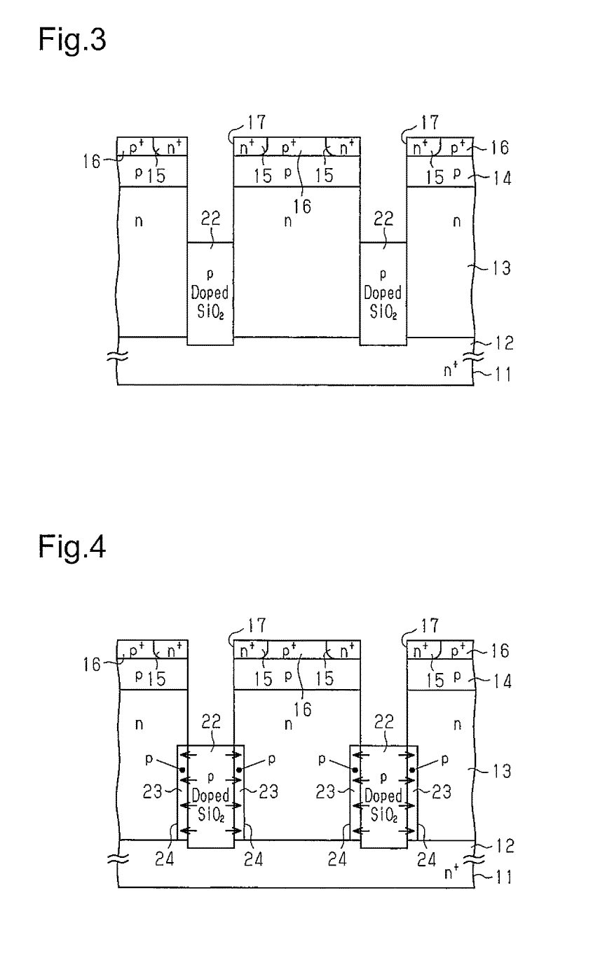

Subsequently, as shown in FIG. 3, a p-type impurity doped silicon oxide film 22 is embedded in the bottom of each trench 17. More specifically, a p-type impurity doped silicon oxide film 22 is deposited on the upper surface of the silicon substrate 11, which includes the trenches 17. Through etch-back, the p-type impurity doped silicon oxide film 22 is removed while leaving portions in the trenches 17.

Further, through heat treatment, p-type impurity is diffused from the p-type impurity doped silicon oxide films 22 to the n silicon layer 13, thereby forming p silicon regions 23 as shown in FIG. 4. That is, p-type impurity is diffused from the p-type impurity doped silicon oxide films 22 to the surrounding to form the p silicon regions 23. Accordingly, p-n junctions 24 are formed at the interface between the p silicon regions 23 and the n silicon layer 13 to extend upward from the interface between the n⁺ silicon layer 12 and the n silicon layer 13.

When p-type impurity is diffused from the p-type impurity doped silicon oxide films 22 to form the p silicon regions 23, the p-type impurity is diffused to the areas below the p-type impurity doped silicon oxide films 22. However, the amount of such impurity is not sufficient to invert the n⁺ silicon layer 12 into a p region.

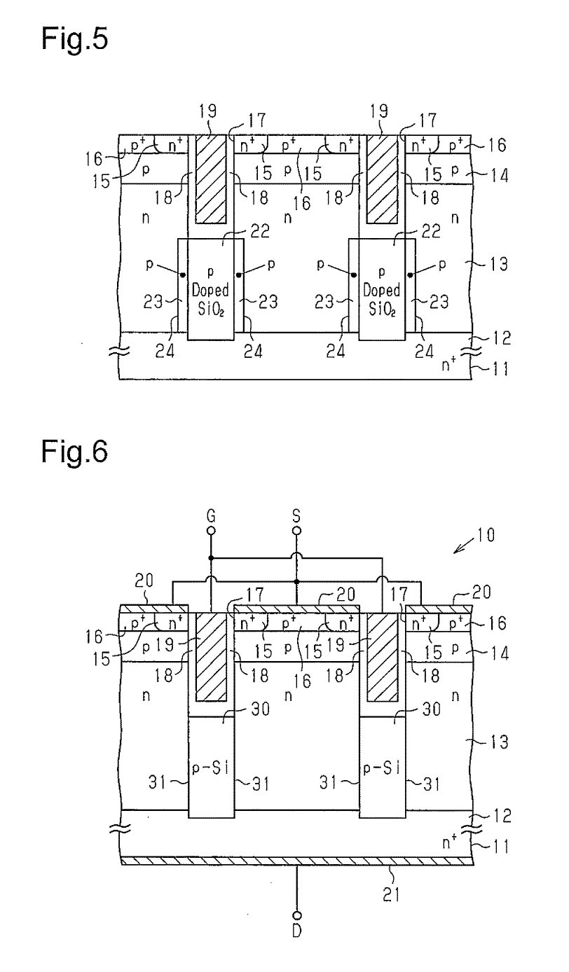

Then, as shown in FIG. 5, a gate oxide film 18 is formed inside each trench 17. Further, a polysilicon gate electrode 19 is arranged in each trench 17 via the gate oxide film 18.

Subsequently, as shown in FIG. 1, a drain electrode 21 is formed on the back side of the silicon substrate 11, and aluminum source electrodes 20 are arranged on predetermined positions on the top surface of the silicon substrate 11. As a result, a trench-gate MOSFET 10 is manufactured.

Next, operation will be described.

As shown in FIG. 1, a width W1 of the n silicon layer 13 (an n-type region), through which a current flows, is ensured without widening the width of the p silicon regions 23. This improves the withstand voltage without degrading the on-resistance.

That is, when the p-type regions 108 are vertically extended to improve the withstand voltage as shown in FIG. 17, ion implantation with an increased accelerating voltage causes the p-type regions 108 to spread in proportion to the depth. This reduces the width W10 of the n-type region that is located between adjacent two gate electrodes 107 (trenches 105) and through which a current actually flows. This increases the on-resistance.

In contrast, in the present embodiment, trenches 17 are first dug to reach the depth of the interface between the n⁺ silicon layer 12 and the n silicon layer 13. Then, the p-type impurity doped silicon oxide films 22, which are oxide films containing p-type impurity, are embedded and diffused laterally, so that the p-type regions are vertically extended without being spread (spread toward the bottom of the trench 17). That is, the p-n junctions 24 can be vertically extended without reducing the width W1 of the n silicon layer 13, through which a current actually flows between the adjacent gate electrode 19 (the trenches 17), and the withstand voltage is improved without degrading the on-resistance.

The present embodiment has the following advantages.

(1) The trench-gate MOSFET has a structure in which the trenches 17 are formed to be deeper than the interface between the n⁺ silicon layer 12 and the n silicon layer 13, and the p-n junction 24 is provided at the side of the bottom-side portion of each trench 17 to extend upward from the interface between the n⁺ silicon layer 12 and the n silicon layer 13. Thus, the width W1 of the n silicon layer 13, through which a current flows, is prevented from being reduced, so that the withstand voltage is improved without degrading the on-resistance.

(2) The method for manufacturing the trench-gate MOSFET includes a first step, a second step, and a third step. In the first step, the trenches 17 are formed to have a depth that is greater than or equal to the depth at which the interface between the n⁺ silicon layer 12 and the n silicon layer 13 exists. In the second step, which is subsequent to the first step, the p-type impurity doped silicon oxide films 22 are embedded in the trenches 17. In the third step, which is subsequent to the second step, p-type impurity is diffused from the p-type impurity doped silicon oxide films 22 to the n silicon layer 13 through heat treatment, thereby forming the p-n junctions 24 to extend upward from the interface between the n⁺ silicon layer 12 and the n silicon layer 13. Accordingly, the trench-gate MOSFET of the above item (1) is manufactured.

(3) In the first step of the above item (2), the trenches 17 are formed to extend to a position deeper than the interface between the n⁺ silicon layer 12 and the n silicon layer 13. Thus, the maximum manufacturing tolerance of the depth of the trenches 17 (manufacturing errors of the wafer) is absorbed, so that the trench-gate MOSFET of the above item (1) is manufactured.

(4) If the concentration of impurity in the n silicon layer 13 is increased, part of the increase effect in the withstand voltage can be shifted to the reduction effect in the on-resistance.

As a modification of the above illustrated embodiment, the p-type impurity doped silicon oxide films 22 may be removed after the p silicon regions 23 are formed as shown in FIG. 4.

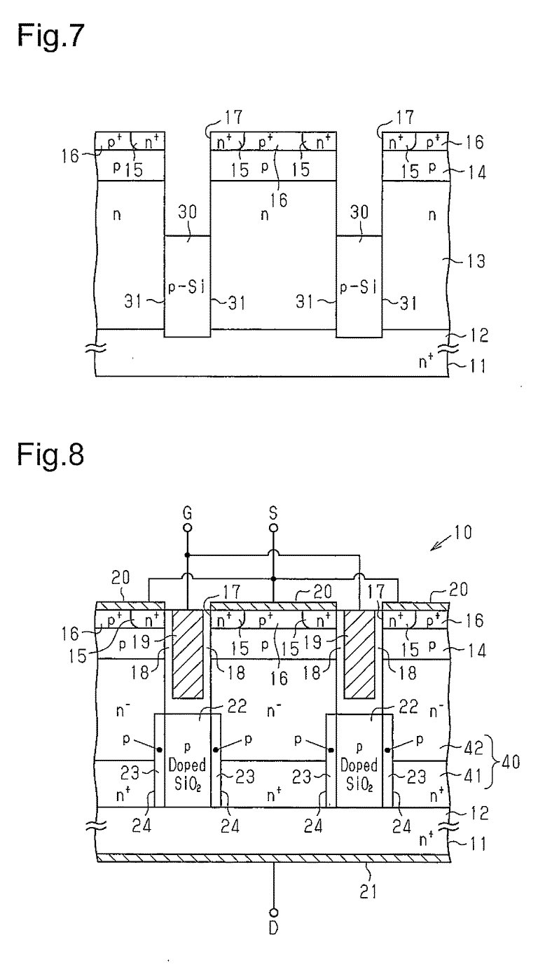

As another modification of the above illustrated embodiment, the structure of FIG. 6 may be employed instead of the structure of FIG. 1. That is, a p-n junction 31 may be formed by a p-type silicon 30, which is embedded in the bottom-side portion of each trench 17, and the n silicon layer 13. To manufacture such a structure, p-type silicon 30 is embedded after the trenches 17 are formed as shown in FIG. 7.

In this manner, the p-n junction 31, which is the junction between the first conductivity type semiconductor and the second conductivity type semiconductor, may be formed by the p-type silicon 30, which a second conductivity type impurity doped semiconductor embedded in the bottom-side portion of the trench 17, and the n silicon layer 13, which is a low concentration first conductivity type semiconductor layer.

Heat treatment may be executed after the p-type silicon 30 is embedded in the trenches 17 to laterally diffuse the p-type impurity. Also, the p-type silicon 30 may be removed after such lateral diffusion of the p-type impurity.

### Second Embodiment

A second embodiment will now be described. Differences from the first embodiment will be mainly discussed.

The second embodiment employs the structure shown in FIG. 8 to ensure the minimum withstand voltage even if the structure shown in FIG. 1 has manufacturing variations.

In FIG. 8, an n silicon layer 40, which replaces the n silicon layer 13 of FIG. 1, is configure by two layers of a lower n⁺ silicon layer 41 and an upper n⁻ silicon layer 42. In a set of n-type silicon and p-type silicon that forms p-n junctions 24, the amounts of n-type impurity and p-type impurity are varied such that the amount of n-type impurity becomes greater toward the n⁺ silicon layer 12 with respect to the thickness direction of the silicon substrate 11.

In this configuration, even if there is imbalance between the amount of p-type impurity and the amount of n-type impurity, that is, even if either the n-type silicon or the p-type silicon has variation in the amount of impurity (the total amount of impurity), the minimum withstand voltage is ensured. Also, in FIG. 8, the vertical dimension (thickness) of a portion of the n⁺ silicon layer 41 that corresponds to the p-n junctions 24, which extend vertically, is equal to the vertical dimension (thickness) of a portion of the n⁻ silicon layer 42 that corresponds to the p-n junction 24.

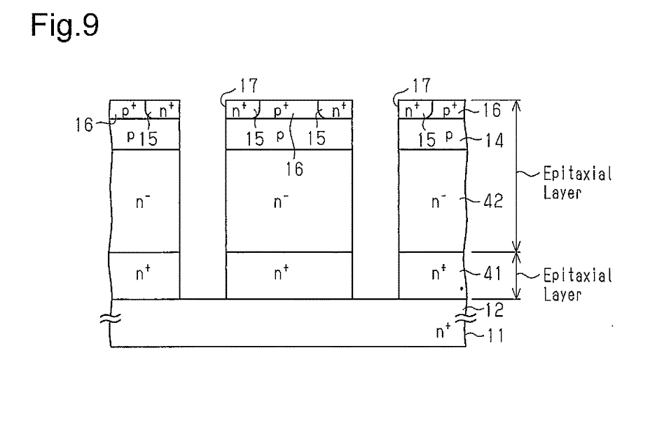

Thus, in the manufacturing process, an epitaxial wafer (an epitaxial substrate) for forming the n silicon layer 40 as shown in FIG. 9 is obtained by a laminated structure of the lower n⁺ silicon layer 41 and the upper n⁻ silicon layer 42. In other words, the epitaxial layer only needs to have multiple (two) layers and other processes do not need to be changed.

A more specific description will be given below.

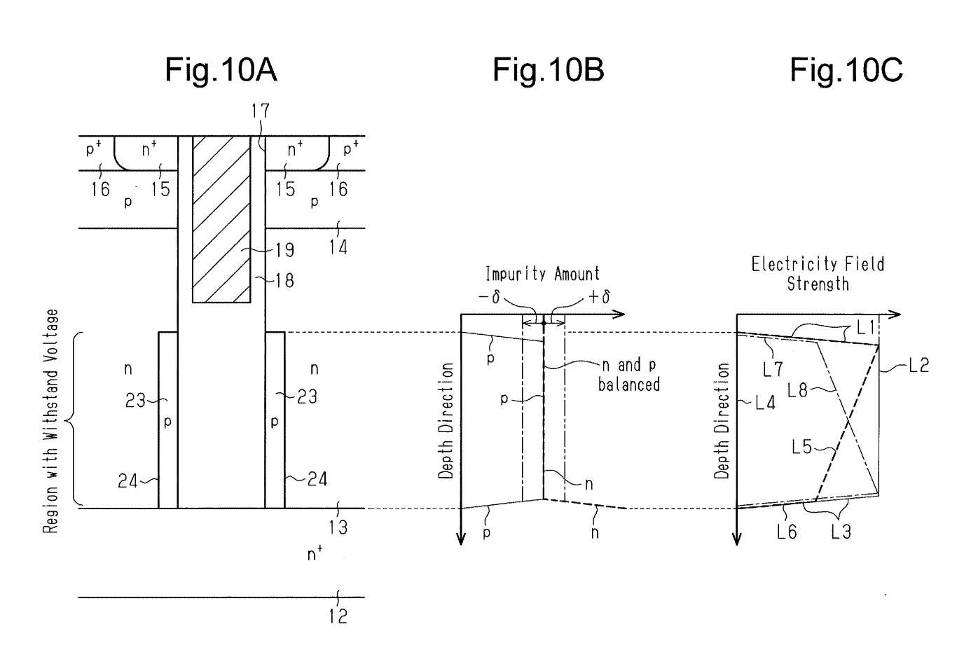

In FIG. 1, increase in the impurity concentration of the n silicon layer 13 lowers the on-resistance. However, such increase in the impurity concentration lowers the withstand voltage. The withstand voltage can be maintained even if the impurity concentration of the n silicon layer 13 is increased to lower the on-resistance. This is because the impurity concentration of the p silicon region 23 is increased at the same time to achieve equilibrium between the p-type impurity amount and the n-type impurity amount. However, when the p-type impurity amount and the n-type impurity amount are imbalanced due to manufacturing variations (for example, variations in impurity concentration of the epitaxial substrate and the degree of diffusion when the p-type impurity is diffused from the p-type impurity doped silicon oxide film 22 to the n silicon layer 13), the withstand voltage will be lowered in proportion to the impurity amount (±δ in FIG. 10B) corresponding to the difference between the p-type impurity amount and the n-type impurity amount (the inclination angle of the electricity field strength with respect to the depth direction increases in FIG. 10C, which lowers the withstand voltage).

FIG. 10A shows a cross-sectional structure of FIG. 1, and the vertically extending p silicon region 23 has a withstand voltage. FIG. 10B shows the distribution of the amount of impurity averaged in the depth direction of the substrate, and FIG. 10C shows the distribution of the electricity field strength in the substrate depth direction when voltage is withstood.

In FIGS. 10A to 10C, under a condition in which the n concentration has the center value in the variation range, the area of the region surrounded by line segments L1, L2, L3, and L4 is proportional to the withstand voltage. Under a condition in which the n concentration has the upper limit value in the variation range, the area of the region surrounded by line segments L1, L5, L6, and L4 is proportional to the withstand voltage. Under a condition in which the n concentration has the lower limit value in the variation range, the area of the region surrounded by line segments L7, L8, L3, and L4 is proportional to the withstand voltage.

Thus, the higher the p-type and n-type impurity concentration is made to lower the on-resistance, the greater the difference between the impurity amounts becomes when variation occurs at the same ratio (for example, percentage). Accordingly, reduction in the withstand voltage becomes great.

In this context, the n silicon layer 40 is made to have two layers as shown in FIG. 8 so that the concentration changes in the middle. This diminishes the influence of the imbalance between the p-type and n-type impurity amounts on the withstand voltage. Accordingly, the variation in the withstand voltage is reduced.

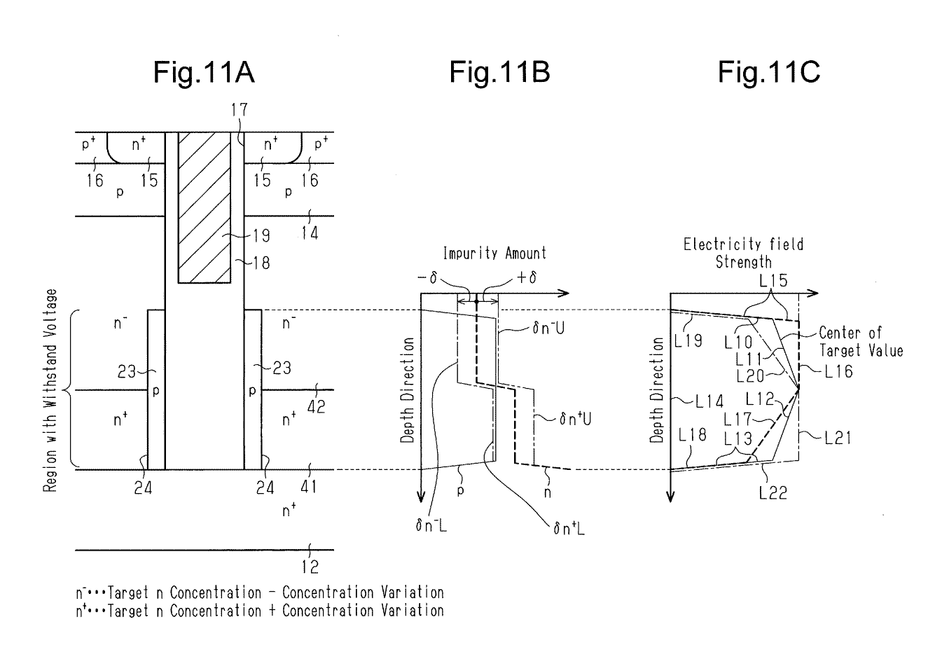

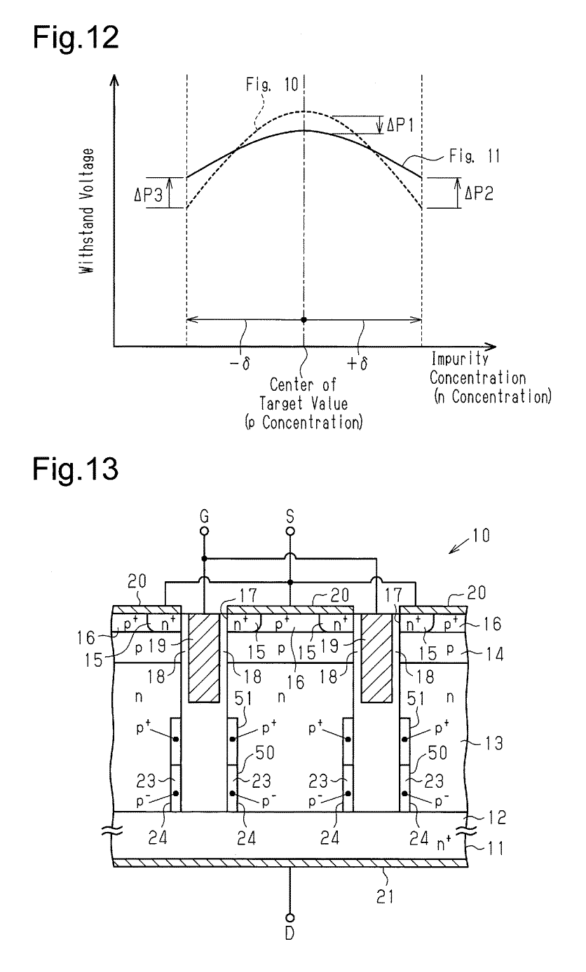

FIG. 11A shows a cross-sectional structure of FIG. 8, and the vertically extending p silicon region 23 has a withstand voltage. FIG. 11B shows the distribution of the amount of impurity averaged in the depth direction of the substrate, and FIG. 11C shows the distribution of the electricity field strength in the substrate depth direction when voltage is withstood.

In FIGS. 11A to 11C, under a condition in which the n concentration has the center value in the variation range, the area of the region surrounded by line segments L10, L11, L12, L13 and L14 is proportional to the withstand voltage. Under a condition in which the n concentration has the upper limit value in the variation range, the area of the region surrounded by line segments L15, L16, L17, L18 and L14 is proportional to the withstand voltage. Under a condition in which the n concentration has the lower limit value in the variation range, the area of the region surrounded by line segments L19, L20, L21, L22 and L14 is proportional to the withstand voltage.

FIGS. 10A to 10C and FIGS. 11A to 11C will now be compared with each other. Under a condition in which the n concentration has the center value in the variation range, the area of the region surrounded by the line segments L10, L11, L12, L13, and L14 of FIGS. 11A to 11C is smaller than the area of the region surrounded by the line segments L1, L2, L3, and L4 of FIGS. 10A to 10C. That is, the corresponding withstand voltage is lower in FIGS. 11A to 11C than in FIGS. 10A to 10C in this case. Under a condition in which the n concentration has the upper limit value in the variation range, the area of the region surrounded by the line segments L15, L16, L17, L18, and L14 of FIGS. 11A to 11C is larger than the area of the region surrounded by the line segments L1, L5, L6, and L4 of FIGS. 10A to 10C. That is, the corresponding withstand voltage is higher in FIGS. 11A to 11C than in FIGS. 10A to 10C in this case. Further, under a condition in which the n concentration has the lower limit value in the variation range, the area of the region surrounded by the line segments L19, L20, L21, L22, and L14 of FIGS. 11A to 11C is larger than the area of the region surrounded by the line segments L7, L8, L3, and L4 of FIGS. 10A to 10C. That is, the corresponding withstand voltage is higher in FIGS. 11A to 11C than in FIGS. 10A to 10C in this case.

The area of the region surrounded by the line segments L15, L16, L17, L18, and L14 of FIG. 11A to 11C is equal to the area of the region surrounded by the line segments L19, L20, L21, L22 and L14 of FIGS. 11A to 11C. That is, the corresponding withstand voltages are equal to each other. That is, variation in the withstand voltage is diminished. In FIGS. 10A to 10C and 11A to 11C, the impurity concentration of the p silicon region 23 is constant.

FIG. 12 shows the withstand voltage when the n concentration is uneven with respect to the center of a target value of the p concentration.

As shown in FIG. 10B, the withstand voltage is lowered due to the concentration variation ±δ of the n-type impurity as shown in FIG. 10C. The concentration variation ±δ of the n-type impurity refers to a range between the variation lower limit −δ and the variation upper limit +δ of the n-type impurity concentration with respect to the balanced impurity amounts of the n-type and p-type. As a result, the center of the target value of the withstand voltage (the maximum withstand voltage), which is the critical electricity field strength (the limit of the electricity field strength), is lowered by a predetermined amount ΔP1 as shown in FIG. 12 in the structure of FIG. 8 compared to the structure of FIG. 1. However, at the upper limit and the lower limit of the variation, the withstand voltage of the structure of FIG. 8 is higher than that of the structure of FIG. 1 by predetermined amounts AP2 and AP3, respectively.

That is, when the n-type impurity concentration is at the n concentration upper limit as indicated by the sign L5 in FIG. 10C, that is, when the n-type impurity concentration is greater than the p-type impurity concentration, the electricity field strength decreases as the depth in the substrate increases. In contrast, when the n-type impurity concentration is at the n concentration lower limit as indicated by the sign LB in FIG. 10C, that is, when the n-type impurity concentration is less than the p-type impurity concentration, the electricity field strength increases as the depth in the substrate increases. Since the area of the region surrounded by the line segments L1, L5, L6, and L4 and the area of the region surrounded by the line segments L7, L8, L3, and L4 are proportional to the withstand voltage, the withstand voltage is reduced regardless whether the n-type impurity concentration is high or low.

On the other hand, in FIG. 11B, the impurity concentration of the n⁻ silicon layer 42 has an upper limit δn⁻U and lower limit δn⁻L of variation, and the n⁺ silicon layer 41 has an upper limit δn⁺U and lower limit δn⁺L of variation. The impurity concentration of the p silicon region 23 is set to the variation upper limit of the impurity concentration of the n⁻ silicon layer 42, and the impurity concentration of the p silicon region 23 is set to the variation lower limit of the impurity concentration of the n⁺ silicon layer 41. That is, the impurity concentration of the n⁻ silicon layer 42 is a value obtained by subtracting a variation from the target n concentration, and the impurity concentration of the n⁺ silicon layer 41 is a value obtained by adding a variation to the target n concentration. Thus, as shown in FIG. 11C, the critical electricity field strength (the limit of the electricity field strength) is the difference between the n⁺ silicon layer 41 and the n⁻ silicon layer 42. In FIG. 11C, the area of the region surrounded by the line segments L15, L16, L17, L18, and L14 and the area of the region surrounded by the line segments L19, L20, L21, L22, and L14 are proportional to the withstand voltage. Therefore, when the n-type impurity concentration is uneven, the reduction in the withstand voltage is less than that in the structure of FIG. 1.

As described above, the reduction in the withstand voltage due to manufacturing variation in the structure of FIG. 1 is diminished by the structure of FIG. 8, improving the withstand voltage at the upper limit and lower limit of variation. That is, the variation in the property is reduced in relation to the variation in the structure.

The present embodiment has the following advantages.

(5) A set of n-type silicon, which is the first conductivity type semiconductor, and p-type silicon, which is the second conductivity type semiconductor, forms the p-n junctions 24. In the set, the amounts of n-type impurity and p-type impurity are varied such that the amount of n-type impurity becomes greater toward the n⁺ silicon layer 12, which is a high concentration first conductivity type semiconductor layer, with respect to the thickness direction of the silicon substrate 11, which is a semiconductor substrate. Therefore, even if the amount of impurity is uneven in either one of the n-type silicon and the p-type silicon, which constitute the p-n junctions 24, the minimum withstand voltage is ensured.

(6) The two-layer structure varies the amounts of the n-type impurity and p-type impurity. Therefore, even if the amount of impurity is uneven in either one of the n-type silicon and the p-type silicon, which constitute the p-n junctions 24, the minimum withstand voltage is easily ensured.

As a modification of the above illustrated embodiment, the structure shown in FIG. 8 may be replaced by the structure shown in FIG. 13. That is, the p silicon regions 23 are each divided into two layers at a point in the depth direction of the substrate. Specifically, the p silicon regions 23 are each divided at the same dimension (the same depth) in the vertical direction into a lower p⁻ silicon layer 50 and an upper p⁺ silicon layer 51. In this case, a set of n-type silicon, which is the first conductivity type semiconductor, and p-type silicon, which is the second conductivity type semiconductor, forms the p-n junctions 24. In the set, the amounts of n-type impurity and p-type impurity are varied such that the amount of p-type impurity, which is impurity of a second conductivity type, becomes smaller toward the n⁺ silicon layer 12, which is a high concentration first conductivity type semiconductor layer, with respect to the thickness direction of the silicon substrate 11, which is a semiconductor substrate.

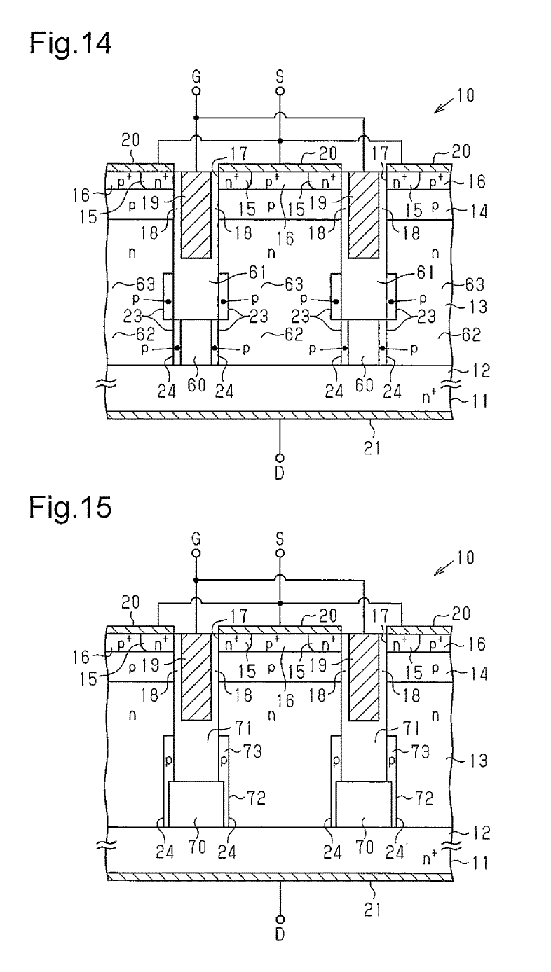

As a modification of the above illustrated embodiment, the structure shown in FIG. 8 may be replaced by the structure shown in FIG. 14. That is, the width of the trenches 17 is changed at a point in the depth direction of the substrate. Specifically, each trench 17 has a lower narrow portion 60 and an upper wide portion 61, so that the width of the n silicon layer 13 varies between the position corresponding to the wide portions 62 and the position corresponding to the narrow portion 63. In this case, a set of n-type silicon, which is the first conductivity type semiconductor, and p-type silicon, which is the second conductivity type semiconductor, forms the p-n junctions 24. In the set, the amounts of n-type impurity and p-type impurity are varied such that the amount of n-type impurity becomes greater toward the n⁺ silicon layer 12, which is a high concentration first conductivity type semiconductor layer, with respect to the thickness direction of the silicon substrate 11, which is a semiconductor substrate. The p-n junctions 24 are divided into two sections at the same vertical dimension (the same depth) into a section corresponding to the narrow portion 60 and a section corresponding to the wide portion 61.

As a modification of the above illustrated embodiment, the structure shown in FIG. 8 may be replaced by the structure shown in FIG. 15. That is, the p silicon region 23, which has a constant width in FIG. 1, is modified. Specifically, the trench 17 is divided into lower wide portion 70 and an upper narrow portion 71 at a point in the depth direction of the substrate in FIG. 15, so that p silicon region is divided into a lower narrow portion 72 and an upper wide portion 73, accordingly. In this case, a set of n-type silicon, which is the first conductivity type semiconductor, and p-type silicon, which is the second conductivity type semiconductor, forms the p-n junctions 24. In the set, the amounts of n-type impurity and p-type impurity are varied such that the amount of p-type impurity becomes smaller toward the n⁺ silicon layer 12, which is a high concentration first conductivity type semiconductor layer, with respect to the thickness direction of the silicon substrate 11, which is a semiconductor substrate. The p-n junctions 24 are divided into two sections at the same dimension (the same depth) into a section corresponding to the narrow portion 72 and a section corresponding to the wide portion 73.

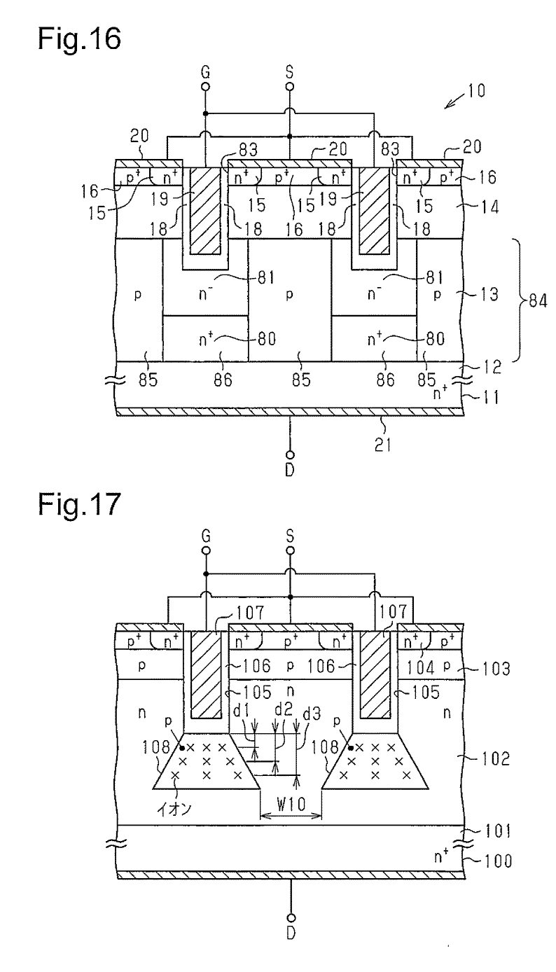

As a modification of the above illustrated embodiment, the structure shown in FIG. 8 may be replaced by the structure shown in FIG. 16. FIG. 16 shows a vertical MOSFET having a super-junction structure, which includes trenches 83, a drift layer 84 below the trenches 83, and n columns (n-type regions) 86 in the drift layer 84. The portion of each n column 86 that is below the bottom of the corresponding trench 83 is divided into two sections of the same vertical dimension (the same depth). The two sections are a lower high concentration portion 80 and an upper low concentration portion 81. In the trench-gate MOSFET having a super-junction structure, in which the p columns (p-type regions) 85 and the n columns (n-type regions) 86 are repeatedly arranged along the planar direction of the substrate 11, each n column (n-type region) 86 is divided into two layers, which are the lower high concentration portion 80 and the upper low concentration portion 81. Thus, when the electricity field strength is made constant to maintain the withstand voltage, reduction in the withstand voltage is minimized.

The present invention is not limited to the above described embodiments, but may be modified as follows.

Regarding the conductivity types of the semiconductors, the p-type and the n-type may be reversed.

In the above illustrated embodiments, side walls of the trenches 17 are perpendicular to the upper surface of the silicon substrate 11. However the side walls of the trenches 17 may be tilted with respect to the upper surface of the silicon substrate 11. That is, the trenches 17 may be V-shaped grooves.

Therefore, the present examples and embodiments are to be considered as illustrative and not restrictive and the invention is not to be limited to the details given herein, but may be modified within the scope and equivalence of the appended claims.

1. A trench-gate semiconductor device comprising:
a semiconductor substrate;
a high concentration first conductivity type semiconductor layer, which is provided in the semiconductor substrate and contains a first conductivity type semiconductor;
a low concentration first conductivity type semiconductor layer, which is provided on the high concentration first conductivity type semiconductor layer in a thickness direction of the semiconductor substrate to contact the high concentration first conductivity type semiconductor layer and contains the first conductivity type semiconductor;
a second conductivity type semiconductor layer, which is provided on the low concentration first conductivity type semiconductor layer to contact the low concentration first conductivity type semiconductor layer;
a first conductivity type semiconductor region provided in a surface portion of the second conductivity type semiconductor layer;
a trench, which extends through the first conductivity type semiconductor region and the second conductivity type semiconductor layer below the first conductivity type semiconductor region, wherein the trench has a depth that is greater than or equal to a depth at which exists an interface between the high concentration first conductivity type semiconductor layer and the low concentration first conductivity type semiconductor layer;
a gate insulation film, which is provided in the trench;
a gate electrode, which is provided in the trench via the gate insulation film;
a second conductivity type semiconductor, which is provided at a position corresponding to a bottom-side portion of the trench; and
a junction between the first conductivity type semiconductor and the second conductivity type semiconductor, the junction is provided at a side of the bottom-side portion of the trench,
wherein the junction extends upward from the interface between the high concentration first conductivity type semiconductor layer and the low concentration first conductivity type semiconductor layer.

2. The trench-gate semiconductor device according to claim 1, wherein
the second conductivity type semiconductor contains a second conductivity type impurity doped oxide film, which is embedded in the bottom-side portion of the trench, and
the junction is a portion at which the low concentration first conductivity type semiconductor layer is joined to a second conductivity type semiconductor region, which has been diffused from the second conductivity type impurity doped oxide film.

3. The trench-gate semiconductor device according to claim 1, wherein
the second conductivity type semiconductor contains a second conductivity type impurity doped semiconductor, which is embedded in the bottom-side portion of the trench, and
the junction is a portion at which the second conductivity type impurity doped semiconductor is joined to the low concentration first conductivity type semiconductor layer.

4. The trench-gate semiconductor device according to claim 1, wherein the first conductivity type semiconductor and the second conductivity type semiconductor, which form the junction, are configured such that an amount of impurity of the first conductivity type and an amount of impurity of the second conductivity type vary such that, in the thickness direction of the semiconductor substrate, the amount of impurity of the first conductivity type increases toward the high concentration first conductivity type semiconductor layer or the amount of impurity of the second conductivity type decreases toward the high concentration first conductivity type semiconductor layer.

5. The trench-gate semiconductor device according to claim 4, wherein a two-layer structure is employed to vary the amount of impurity of the first conductivity type and the amount of impurity of the second conductivity type.

6. A method for manufacturing a trench-gate semiconductor device, the method comprising:
forming a high concentration first conductivity type semiconductor layer on a semiconductor substrate;
forming a low concentration first conductivity type semiconductor layer on the high concentration first conductivity type semiconductor layer in a thickness direction of the semiconductor substrate, such that the low concentration first conductivity type semiconductor layer contacts the high concentration first conductivity type semiconductor layer;
forming a second conductivity type semiconductor layer on the low concentration first conductivity type semiconductor layer to contact the low concentration first conductivity type semiconductor layer;
forming a first conductivity type semiconductor region in a surface portion of the second conductivity type semiconductor layer;
forming a trench, which extends through the first conductivity type semiconductor region and the second conductivity type semiconductor layer below the first conductivity type semiconductor region, wherein the trench has a depth that is greater than or equal to a depth at which exists an interface between the high concentration first conductivity type semiconductor layer and the low concentration first conductivity type semiconductor layer;
after the forming of the trench, embedding a second conductivity type impurity doped oxide film in the trench;
in the embedding, forming a junction between the first conductivity type semiconductor and the second conductivity type semiconductor such that the junction extends upward from an interface between the high concentration first conductivity type semiconductor layer and the low concentration first conductivity type semiconductor layer by diffusing the second conductivity type impurity from the second conductivity type impurity doped oxide film to the low concentration first conductivity type semiconductor layer through heat treatment; and
forming a gate insulation film and a gate electrode in the trench.
